(19) United States
(12) Patent Application Publication
(10) Pub. No.: US 2026/0230067 A1
(43) Pub. Date: Aug. 6, 2026

(54) ALL-DIGITAL TRANSIENT FILTER FOR SERIAL COMMUNICATION LINKS

(71) Applicant: STMicroelectronics International N.V., Geneva (CH)

(72) Inventors: Ankur BAL, Greater Noida (IN); Aradhana KUMARI, Greater Noida (IN)

(21) Appl. No.: 19/453,576

(22) Filed: Jan. 20, 2026

Related U.S. Application Data
(60) Provisional application No. 63/753,193, filed on Feb. 3, 2025.

(51) Int. Cl. H03K 5/1252; H03K 3/037

(52) U.S. Cl. CPC H03K 5/1252; H03K 3/037

(57) ABSTRACT

In accordance with various embodiments of the present disclosure, a transient filter circuit is provided. In some embodiments, the transient filter circuit comprises a rising edge flip-flop (RE FF) and a falling edge flip-flop (FE FF) in parallel to the RE FF. An output signal from the RE FF prevents the FE FF from being triggered by falling edge transients in an input signal to be filtered. An output signal from the FE FF prevents the RE FF from being triggered by rising edge transients in the input signal.

### CROSS-REFERENCE TO RELATED APPLICATIONS

This application claims priority to and the benefit of US Provisional Patent Application Ser. No. 63/753,193, filed Feb. 3, 2025, and titled “ALL-DIGITAL TRANSIENT FILTER FOR SERIAL COMMUNICATION LINKS,” which is incorporated herein by reference in its entirety.

### FIELD OF THE INVENTION

Example embodiments of the present disclosure relate generally to serial communications and, more particularly, transient filters for serial communications.

### BACKGROUND

Chip-to-chip serial communication links, such as I3C, SPI, UART, etc., are used in many applications, such as mobile phones, automotive, Internet-of-Things (IOT), displays, image sensors, mid-speed embedded and deeply-embedded applications across sensors, actuators, power regulators, microcontrollers (MCUs), field programmable gate arrays (FPGAs), etc. In such applications, a transmitter on a first chip or device sends serial data via two lines to a receiver on a second chip or device, and a transmitter on the second device sends serial data via two lines to a receiver on the first device. Such devices may have a single channel of communications (i.e., one transmitter and one receiver per device, each connected to the corresponding receiver or transmitter on the other device via two communication lines), however, multiple similar channels may be present.

Serial links are subject to transient noise and glitches which can plague the system operation, resulting in an increased bit error rate (BER) or even complete failure of communication. External ambient high frequency noise and impedance termination mismatches are primarily responsible for unwanted glitches at the link receiver. Left unaddressed, such glitches may improperly be interpreted as a one or high signal.

The ability to handle such transients/glitches is tested in electromagnetic compatibility (EMC) compliance tests where noise is injected at the receiver, and the serial link performance is monitored. One approach that has been used is to deploy an analog RC filter on the circuit board at the link receiver front end to filter out unwanted high frequency spikes. However, such an RC low pass filter not only adds an inertia to the system, which results in increased link latency, but also occupies valuable space on the circuit board.

Applicant has identified many technical challenges and difficulties associated with filtering transients in serial communications. Through applied effort, ingenuity, and innovation, Applicant has solved problems related to filtering transients in serial communications by developing solutions embodied in the present disclosure, which are described in detail below.

### BRIEF SUMMARY

Various embodiments described herein relate to circuits, devices, and methods for filtering transients from serial communications.

In accordance with various embodiments of the present disclosure, a transient filter circuit is provided. In some embodiments, the transient filter circuit comprises a rising edge flip-flop (RE FF) and a falling edge flip-flop (FE FF) in parallel to the RE FF. An output signal from the RE FF prevents the FE FF from being triggered by falling edge transients in an input signal to be filtered. An output signal from the FE FF prevents the RE FF from being triggered by rising edge transients in the input signal.

In some embodiments, the transient filter circuit further comprises a latch connected downstream of the FE FF and the FE FF that latches and outputs a high signal when the input signal transitions from low to high and latches and outputs a zero when the input signal transitions from high to low.

In some embodiments, the transient filter circuit further comprises an upstream AND gate having a first input that receives the input signal, a second input that receives the output signal from the FE FF, and an output that is connected to a clock input of the RE FF; and an upstream OR gate having a first input that receives the input signal, a second input that receives the output signal from the RE FF, and an output that is connected to a clock input of the FE FF.

In some embodiments, the transient filter circuit further comprises first delay circuitry having an input connected to an output of the RE FF and an output connected to a reset input of the RE FF; and second delay circuitry having an input connected to an output of the FE FF and an output connected to a set input of the FE FF. The first delay circuitry creates a first time delay defining an amount of time after the input signal transitions from low to high for which any transients in the input signal will be filtered. The second delay circuitry creates a second time delay defining an amount of time after the input signal transitions from high to low for which any transients in the input signal will be filtered.

In some embodiments, the first delay circuitry comprises a plurality of inverters in series, with a number of the inverters in the first delay circuitry defining the first time delay, and the second delay circuitry comprises a plurality of inverters in series, with a number of the inverters in the second delay circuitry defining the second time delay.

In some embodiments, the first time delay is selectable and the second time delay is selectable.

In some embodiments, the transient filter circuit further comprises a first downstream AND gate having a first input connected to an inverse output of the RE FF, a second input connected to an inverse output of the FE FF, and an output connected to a first input of the latch; and a second downstream AND gate having a second input connected to an output of the RE FF, a second input connected to an output of the FE FF, and an output connected to a second input of the latch.

In accordance with various embodiments of the present disclosure, an electronic device is provided. In some embodiments, the electronic device comprises a transient filter circuit comprising a rising edge flip-flop (RE FF) and a falling edge flip-flop (FE FF) in parallel to the RE FF, and receiving circuitry connected to an output of the transient filter circuit to receive a filterer version of an input signal. An output signal from the RE FF prevents the FE FF from being triggered by falling edge transients in an input signal to be filtered. An output signal from the FE FF prevents the RE FF from being triggered by rising edge transients in the input signal.

In accordance with various embodiments of the present disclosure, a transient filter circuit is provided. In some embodiments, the transient filter circuit comprises a rising edge flip-flop (RE FF); a falling edge flip-flop (FE FF) in parallel to the RE FF; an upstream AND gate having a first input that receives an input signal, a second input that receives an output signal from the FE FF, and an output that is connected to a clock input of the RE FF; an upstream OR gate having a first input that receives the input signal, a second input that receives an output signal from the RE FF, and an output that is connected to a clock input of the FE FF; first delay circuitry having an input connected to an output of the RE FF and an output connected to a reset input of the RE FF, the first delay circuitry creating a first time delay defining an amount of time after the input signal transitions from low to high for which any transients in the input signal will be filtered; second delay circuitry having an input connected to an output of the FE FF and an output connected to a set input of the FE FF, the second delay circuitry creating a second time delay defining an amount of time after the input signal transitions from high to low for which any transients in the input signal will be filtered; a first downstream AND gate having a first input connected to an inverse output of the RE FF, a second input connected to an inverse output of the FE FF, and an output connected to a first input of a latch; and a second downstream AND gate having a second input connected to an output of the RE FF, a second input connected to an output of the FE FF, and an output connected to a second input of the latch. An output signal from the RE FF prevents the FE FF from being triggered by falling edge transients in an input signal to be filtered. An output signal from the FE FF prevents the RE FF from being triggered by rising edge transients in the input signal. The latch latches and outputs a high signal when the input signal transitions from low to high and latches and outputs a zero when the input signal transitions from high to low.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a block diagram of an example system for filtering transients from serial communications between two devices, in accordance with some embodiments of the present disclosure;

FIG. 2 is a circuit diagram of an example transient filter circuit, in accordance with some embodiments of the present disclosure;

FIG. 3 is a timing diagram of signals in the example transient filter circuit of FIG. 2, in accordance with some embodiments of the present disclosure; and

FIG. 4 is a circuit diagram of an example delay circuit of an example transient filter circuit, in accordance with some embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing example circuits, devices, and methods for filtering transients from serial communications. Various embodiments of the present disclosure may be implemented in any suitable device (including but not limited to mobile phones, displays, image sensors, etc.) having one or more serial communication links (including but not limited to I3C, SPI, UART, I2C.

Various embodiments of the present disclosure are directed to an on-chip all-digital asynchronous (i.e., does not require an external clock) transient/glitch filter for semiconductor devices (“chips”) having serial communication links, such as might conform to one or more communication standards such as I3C, SPI, UART, etc. In various embodiments, the transient filter circuit resides just before the receiver front end, but on-chip rather than off-chip (i.e., on the circuit board) as is the RC filter described above. Embodiments of the present disclosure are described and illustrated herein in relation to an I3C clock (“SCL”) line but can be used with any suitable serial communication line.

In various embodiments, the transient filter circuit comprises a rising edge flip-flop (RE FF) and a falling edge flip-flop (FE FF), with the RE FF preventing the FE FF from being triggered by falling edge glitches and the FE FF preventing the RE FF from being triggered by rising edge glitches. In various embodiments, an arrangement of downstream AND gates and a latch provides the output of the transient filter circuit by latching a high signal when the data line goes high and latching a low signal when the data line goes low.

In such applications, a transmitter on a first chip or device sends serial data via two lines to a receiver on a second chip or device, and a transmitter on the second device sends serial data via two lines to a receiver on the first device. Such devices may have a single channel of communications, however, multiple similar channels may be present.

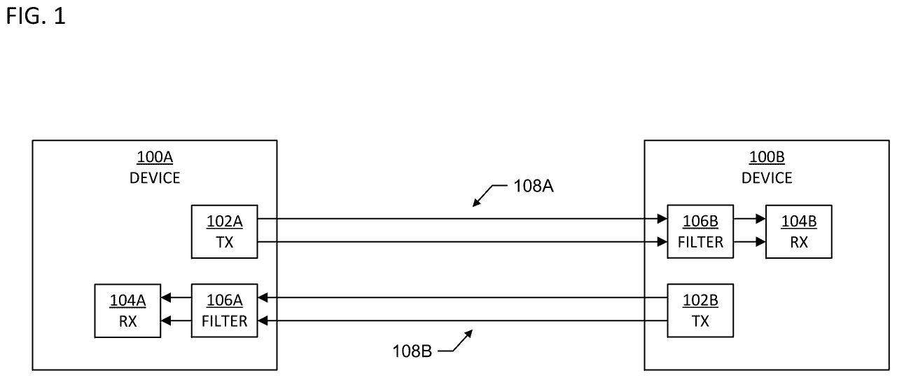

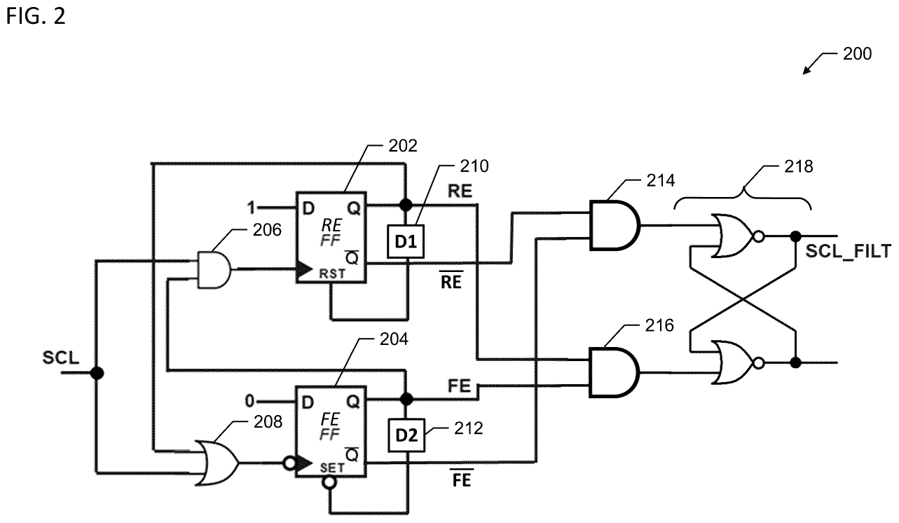

Referring now to FIG. 1, a block diagram of an example system for filtering transients from serial communications between two devices is illustrated in accordance with some embodiments of the present disclosure. The system of FIG. 1 comprises a first device 100A and a second device 100B with a serial communication link therebetween. The first device 100A comprises a transmitter 102A, a receiver 104A, and a transient filter 106A. The second device 100B comprises a transmitter 102B, a receiver 104B, and a transient filter 106B. Although not illustrated in FIG. 1, the transient filters 106A and 106B each comprise two transient filter circuits as described below in relation to FIG. 2, one transient filter circuit for each communication line.

As illustrated in FIG. 1, the first device 100A transmits serial data via the transmitter 102A over a first pair of wires 108A. The data transmitted by the first device 100A is received first by the transient filter 106B of the second device 100B. The transient filter 106B filters out any transients or glitches that occur within a predefined amount of time of the signals on the wires 108A going from low to high or from high to low. The filtered data is then provided to the receiver 104B on the second device 100B to be used as needed. Similarly, the second device 100B transmits serial data via the transmitter 102B over a second pair of wires 108B. The data transmitted by the second device 100B is received first by the transient filter 106A of the first device 100A. The transient filter 106A filters out any transients or glitches that occur within a predefined amount of time of the signals on the wires 108B going from low to high or from high to low. The filtered data is then provided to the receiver 104A on the first device 100A to be used as needed.

FIG. 2 illustrates a circuit diagram of an example transient filter circuit, in accordance with some embodiments of the present disclosure. Embodiments of the present disclosure are described and illustrated herein in relation to an I3C clock (“SCL”) line but can be used with any serial communication line.

As illustrated in FIG. 2, embodiments of the present disclosure comprise a rising edge flip-flop (RE FF) 202 and a falling edge flip-flop (FE FF) 204. The serial line to be filtered (SCL in FIG. 2) is provided to an upstream AND gate 206 and an upstream OR gate 208. The output of the FE FF 204 (this output is labeled Q and the output signal is labeled FE in FIG. 2) is connected to the other input of the upstream AND gate 206 and the output of the RE FF 202 (this output is labeled Q and the output signal is labeled RE in FIG. 2) is connected to the other input of the upstream OR gate 208. The output of the upstream AND gate 206 is connected to the clock input to the RE FF 202 (indicated by the triangle at the input), and the output of the upstream OR gate 208 is connected to the clock input to the FE FF 204 (indicated by the triangle at the input).

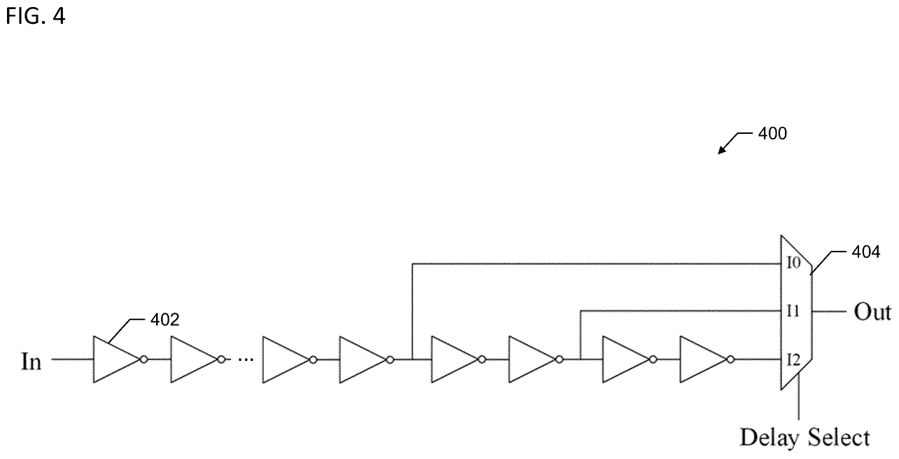

A first delay circuit (D1) 210 is connected between the output of the RE FF 202 and its RST input and a second delay circuit (D2) 210 is connected between the output of the FE FF 204 and its SET input. As described further below in relation to FIG. 4, the delay circuits may be provided by a plurality of inverters in series, with the number of inverters used optionally being selectable as needed to select the length of the delay.

Two AND gates are positioned downstream of the flip-flops. The inverse output of the RE FF 202 (this output is labeled Q̅ and the output signal is labeled R̅E̅ in FIG. 2) and inverse output of the FE FF 204 (this output is labeled Q̅ and the output signal is labeled F̅E̅ in FIG. 2) are connected to a first downstream AND gate 214 while the output of the RE FF 202 (this output is labeled Q and the output signal is labeled RE in FIG. 2) and the output of the FE FF 204 (this output is labeled Q and the output signal is labeled FE in FIG. 2) are input to a second downstream AND gate 216. A latch 218 (such as an RS latch) is connected downstream to the two downstream AND gates 214 and 216. The output of the first downstream AND gate 214 is the R input of the latch 218 and the output of the second downstream AND gate 216 is the S input of the latch 218.

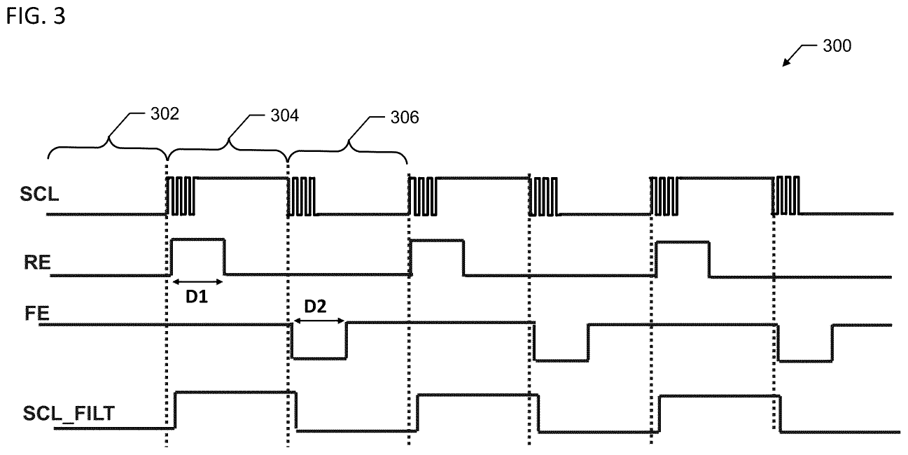

The operation of the digital transient filter 200 of FIG. 2 will be described in conjunction with FIG. 3 in which a timing diagram 300 of signals in the example transient filter circuit 200 is illustrated. FIG. 3 shows the states of the line to be filtered (SCL), the output signal (RE) from the RE FF 202, the output signal (FE) from the FE FF 204, and the output of the filter circuit (SCL_FILT). As seen in FIG. 3, the SCL line has transients (i.e., several high frequency transitions between low and high) right after each transition from low to high or from high to low. The transients (or glitches) typically only last for a short period of time. In various embodiments, the delay provided by the delay circuits 210 (D1) and 212 (D2) is selected such that the delay is long enough that the transients will be over before the delay elapses. In various embodiments, the amount of delay may be fixed or may be selectively variable, depending on the design of the delay circuits.

In the initial condition period 302, the RE FF 202 is at RST which means that RE=0 or low, and the FE FF 204 is at SET which means that FE=1 or high. When SCL goes to 1 (high) (e.g., at the beginning of period 304), both inputs to the upstream AND gate 206 are 1 which triggers the RE FF 202 and RE goes to 1.

Because RE (1) is input to the upstream OR gate 208, the output of the upstream OR gate 208 remains 1 regardless of whether SCL glitches and goes rapidly low and high. This prevents the FE FF 204 from being triggered. These transients after SCL goes high do not affect the output of the RE FF 202—any rising edges of the transients simply “re-trigger” the RE FF 202 and any falling edges of the transients do nothing because RE FF 202 is a rising edge FF.

After the delay provided by the delay circuit (D1) 210 elapses, RE (1) is provided to the RST input and resets the RE FF 202 to 0. This is seen in period 304 of FIG. 3 when RE goes low.

Now that RE, which is input to the upstream OR gate 208, is 0, the SCL signal controls the FE FF 204. When SCL goes low (0) (e.g., at the beginning of period 306), this triggers the FE FF 204 and FE goes from 1 to 0.

Because FE (0) is input to the upstream AND gate 206, the output of the upstream AND gate 206 remains 0 regardless of whether SCL glitches and goes rapidly high and low. This prevents the RE FF 202 from being triggered. These transients after SCL goes low do not affect the output of the FE FF 204—any falling edges of the transients simply “re-trigger” the FE FF 204 and any rising edges of the transients do nothing because FE FF 204 is a falling edge FF.

After the delay provided by the delay circuit (D2) 212 elapses, FE (0) is provided to the SET input and sets the FE FF 204 to 1. This is seen in period 306 of FIG. 3 where the FE signal goes high.

To summarize so far, the RE FF 202 is preventing the FE FF 204 from being triggered by falling edge transients, and the FE FF 204 is preventing the RE FF 202 from being triggered by rising edge transients.

As described above, the inverse output signal R̅E̅ of the RE FF 202 and the inverse output signal F̅E̅ of the FE FF 204 are input to the first downstream AND gate 214, and the output RE of the RE FF 202 and the output FE of the FE FF 204 are input to the second downstream AND gate 216. This arrangement of the downstream AND gates 214, 216 and the latch 218 provides the output of the filter circuit by latching a 1 when SCL goes high and latching a 0 when SCL goes low.

When SCL goes high, signal R̅E̅ is 0 and signal F̅E̅ is 0 which means that the output of the first downstream AND gate 214 is 0, and RE is 1 and FE is 1 which means that the output of the second downstream AND gate 216 is 1. This means that the output of the latch 218 (and of the filter circuit 200) SCL_FILT is 1 and stays 1 until the latch inputs R and S change state. So after SCL goes high, SCL_FILT is 1 and stays 1 regardless of any transients.

When SCL goes low, signal R̅E̅ is 1 and signal F̅E̅ is 1 which means that the output of the first downstream AND gate 214 is 1, and RE is 0 and FE is 0 which means that the output of the second downstream AND gate 216 is 0. This means that the output of the latch 218 (and of the filter circuit 200) SCL_FILT goes from 1 to 0 and stays 0 until the latch inputs change state. So after SCL goes low, SCL_FILT is 0 and stays 0 regardless of any transients.

As described above, in various embodiments, the delay provided by the delay circuits 210 (D1) and 212 (D2) is selected such that the delay is long enough that the transients will be over before the delay elapses. The amount of delay provided by the delay circuits 210 (D1) and 212 (D2) will likely be the same, but not necessarily. The amount of delay needed may be, for example, determined experimentally. As described above, the delay circuits 210 (D1) and 212 (D2) may comprise a plurality of inverters in series, with the number of inverters used optionally being selectable as needed to select the length of the delay.

In various embodiments, such delay circuits may be implemented in any suitable manner. FIG. 4 is a circuit diagram of an example delay circuit of an example transient filter circuit, in accordance with some embodiments of the present disclosure. In the illustrated embodiment of FIG. 4, the delay circuit has a selectable delay. The delay circuit 400 of FIG. 4 comprises a plurality of inverters 402 in series. In FIG. 4, eight inverters are shown, but the three dots between the second and third inverters indicate that any suitable number of inverters may be added (however, there should be an even number of inverters so that the value of the delay signal is not inverted). The delay circuit 400 of FIG. 4 further comprises a multiplexer 404 to enable different quantities of the inverters 402 to be selected to be used in the circuit, thereby changing the delay time (i.e., the more inverters used in the circuit, the longer the delay time).

In various embodiments, the input (“In”) of the delay circuit 400 is connected to the output of the RE FF 202 (labeled Q) or to the output of the FE FF 204 (labeled Q), depending on whether the delay circuit 400 is being used as the first delay circuit D1 or the second delay circuit D2. In various embodiments, the output (“Out”) of the delay circuit 400 is connected to the RST input of the RE FF 202 or to the SET input of the FE FF 204, depending on whether the delay circuit 400 is being used as the first delay circuit D1 or the second delay circuit D2. In various embodiments, the select input (“Delay Select”) of the multiplexer 404 may be set during testing at the factory, during setup, or during operation, such as by control circuitry (not illustrated) on the device (e.g., 100A or 100B) on which the delay circuit resides. In the illustrated embodiment, if input I2 of the multiplexer 404 is selected, then all of the inverters 402 are used and the maximum delay is provided. Similarly, if input I1 of the multiplexer 404 is selected, then all of the inverters 402 except the last two are used and slightly less delay is provided. If input I0 of the multiplexer 404 is selected, then all of the inverters 402 except the last four are used and even less delay is provided. In various embodiments, any suitable number of inverters may be used and any suitable number of multiplexer selections may be available.

The transient filter circuit of various embodiments of the present disclosure provides a low cost, all-digital filtering solution circuit for filtering out glitches and transients that may occur in a serial link data, clock bus, etc. The transient filter circuit of various embodiments of the present disclosure is internal to the chip and replaces the traditional RC filter that is placed just before the receiver on the board, outside of the chip. The transient filter circuit of various embodiments of the present disclosure occupies very little space on the chip and can be accommodated in existing design of serial links. The insertion latency of the transient filter circuit of various embodiments is low, does not vary the signal transition width and preserves the signal width/duty cycle of the received signal. The transient filter circuit of various embodiments of the present disclosure is all-digital and thus highly technology independent, enabling very short development times. The transient filter circuit of various embodiments of the present disclosure provides an asynchronous (no need for a high frequency clock for oversampling), low power solution, with sharp filter output signal transitions, low latency (input to output signal latency datapath is approximately five logic gates, with a latency on the order of picoseconds), and which retains the signal pulse width from input to output.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of electronic device which uses serial communications, including but not limited to mobile phones, cameras displays, etc. The serial link can be used to communicate between chips on a single printed circuit board (PCB) or between chips mounted on different PCBs.

Within the appended claims, unless the specific term “means for” or “step for” is used within a given claim, it is not intended that the claim be interpreted under 35 U.S.C. 112, paragraph 6.

What is claimed is:

1. A transient filter circuit comprising:
a rising edge flip-flop (RE FF); and
a falling edge flip-flop (FE FF) in parallel to the RE FF;
wherein an output signal from the RE FF prevents the FE FF from being triggered by falling edge transients in an input signal to be filtered; and
wherein an output signal from the FE FF prevents the RE FF from being triggered by rising edge transients in the input signal.

2. The transient filter circuit of claim 1, further comprising:
a latch connected downstream of the FE FF and the FE FF that latches and outputs a high signal when the input signal transitions from low to high and latches and outputs a zero when the input signal transitions from high to low.

3. The transient filter circuit of claim 2, further comprising:
an upstream AND gate having a first input that receives the input signal, a second input that receives the output signal from the FE FF, and an output that is connected to a clock input of the RE FF; and
an upstream OR gate having a first input that receives the input signal, a second input that receives the output signal from the RE FF, and an output that is connected to a clock input of the FE FF.

4. The transient filter circuit of claim 3, further comprising:
first delay circuitry having an input connected to an output of the RE FF and an output connected to a reset input of the RE FF; and
second delay circuitry having an input connected to an output of the FE FF and an output connected to a set input of the FE FF;
wherein the first delay circuitry creates a first time delay defining an amount of time after the input signal transitions from low to high for which any transients in the input signal will be filtered; and
wherein the second delay circuitry creates a second time delay defining an amount of time after the input signal transitions from high to low for which any transients in the input signal will be filtered.

5. The transient filter circuit of claim 4, wherein the first delay circuitry comprises a plurality of inverters in series, with a number of the inverters in the first delay circuitry defining the first time delay; and
wherein the second delay circuitry comprises a plurality of inverters in series, with a number of the inverters in the second delay circuitry defining the second time delay.

6. The transient filter circuit of claim 4, wherein the first time delay is selectable; and
wherein the second time delay is selectable.

7. The transient filter circuit of claim 4, further comprising:
a first downstream AND gate having a first input connected to an inverse output of the RE FF, a second input connected to an inverse output of the FE FF, and an output connected to a first input of the latch; and
a second downstream AND gate having a second input connected to an output of the RE FF, a second input connected to an output of the FE FF, and an output connected to a second input of the latch.

8. An electronic device comprising:
(i) a transient filter circuit comprising:
a rising edge flip-flop (RE FF); and
a falling edge flip-flop (FE FF) in parallel to the RE FF;
wherein an output signal from the RE FF prevents the FE FF from being triggered by falling edge transients in an input signal to be filtered; and
wherein an output signal from the FE FF prevents the RE FF from being triggered by rising edge transients in the input signal; and
(ii) receiving circuitry connected to an output of the transient filter circuit to receive a filterer version of the input signal.

9. The electronic device of claim 8, wherein the transient filter circuit further comprises:
a latch connected downstream of the FE FF and the FE FF that latches and outputs a high signal when the input signal transitions from low to high and latches and outputs a zero when the input signal transitions from high to low.

10. The electronic device of claim 9, wherein the transient filter circuit further comprises:
an upstream AND gate having a first input that receives the input signal, a second input that receives the output signal from the FE FF, and an output that is connected to a clock input of the RE FF; and
an upstream OR gate having a first input that receives the input signal, a second input that receives the output signal from the RE FF, and an output that is connected to a clock input of the FE FF.

11. The electronic device of claim 10, wherein the transient filter circuit further comprises:
first delay circuitry having an input connected to an output of the RE FF and an output connected to a reset input of the RE FF; and
second delay circuitry having an input connected to an output of the FE FF and an output connected to a set input of the FE FF;
wherein the first delay circuitry creates a first time delay defining an amount of time after the input signal transitions from low to high for which any transients in the input signal will be filtered; and
wherein the second delay circuitry creates a second time delay defining an amount of time after the input signal transitions from high to low for which any transients in the input signal will be filtered.

12. The electronic device of claim 11, wherein the first delay circuitry of the transient filter circuit comprises a plurality of inverters in series, with a number of the inverters in the first delay circuitry defining the first time delay; and
wherein the second delay circuitry of the transient filter circuit comprises a plurality of inverters in series, with a number of the inverters in the second delay circuitry defining the second time delay.

13. The electronic device of claim 11, wherein the first time delay is selectable; and
wherein the second time delay is selectable.

14. The electronic device of claim 11, wherein the transient filter circuit further comprises:
a first downstream AND gate having a first input connected to an inverse output of the RE FF, a second input connected to an inverse output of the FE FF, and an output connected to a first input of the latch; and
a second downstream AND gate having a second input connected to an output of the RE FF, a second input connected to an output of the FE FF, and an output connected to a second input of the latch.

15. A transient filter circuit comprising:
a rising edge flip-flop (RE FF);
a falling edge flip-flop (FE FF) in parallel to the RE FF;
an upstream AND gate having a first input that receives an input signal, a second input that receives an output signal from the FE FF, and an output that is connected to a clock input of the RE FF;
an upstream OR gate having a first input that receives the input signal, a second input that receives an output signal from the RE FF, and an output that is connected to a clock input of the FE FF;
first delay circuitry having an input connected to an output of the RE FF and an output connected to a reset input of the RE FF, the first delay circuitry creating a first time delay defining an amount of time after the input signal transitions from low to high for which any transients in the input signal will be filtered;
second delay circuitry having an input connected to an output of the FE FF and an output connected to a set input of the FE FF, the second delay circuitry creating a second time delay defining an amount of time after the input signal transitions from high to low for which any transients in the input signal will be filtered;
a first downstream AND gate having a first input connected to an inverse output of the RE FF, a second input connected to an inverse output of the FE FF, and an output connected to a first input of a latch; and
a second downstream AND gate having a second input connected to an output of the RE FF, a second input connected to an output of the FE FF, and an output connected to a second input of the latch;
wherein an output signal from the RE FF prevents the FE FF from being triggered by falling edge transients in an input signal to be filtered;
wherein an output signal from the FE FF prevents the RE FF from being triggered by rising edge transients in the input signal;
wherein the latch latches and outputs a high signal when the input signal transitions from low to high and latches and outputs a zero when the input signal transitions from high to low.

16. The transient filter circuit of claim 15, wherein the first delay circuitry comprises a plurality of inverters in series, with a number of the inverters in the first delay circuitry defining the first time delay; and
wherein the second delay circuitry comprises a plurality of inverters in series, with a number of the inverters in the second delay circuitry defining the second time delay.

17. The transient filter circuit of claim 15, wherein the first time delay is selectable; and
wherein the second time delay is selectable.
